(19) United States
(12) Patent Application Publication
(10) Pub. No.: US 2015/0313033 A1
(43) Pub. Date: Oct. 29, 2015

(54) PROTECTION DEVICE FOR AN ELECTRONIC DEVICE

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventors: MING-CHANG LEE, New Taipei (TW); YU-HUA WU, Shenzhen (CN); HONG-LIANG PU, Shenzhen (CN)

(21) Appl. No.: 14/610,750

(22) Filed: Jan. 30, 2015

(30) Foreign Application Priority Data
Apr. 29, 2014 (CN) 201410175114.X

(51) Int. Cl. H05K 5/03; H05K 5/02; B65D 5/52; H05K 5/00

(52) U.S. Cl. CPC H05K 5/03; H05K 5/0086; H05K 5/0234; H05K 5/0226; B65D 5/52

(57) ABSTRACT

A protection device includes a receiving portion capable of receiving an electronic device and a cover pivotally connected to one side of the receiving portion for opening or covering the receiving portion. The cover includes a first reinforcing member, a second reinforcing member, two third reinforcing members symmetrically located at two opposite sides of the first reinforcing member, two fourth reinforcing members located between the two third reinforcing members and the second reinforcing member, two fifth reinforcing member symmetrically located at two opposite sides of the third reinforcing member, and two sixth reinforcing members respectively located between the two fourth reinforcing members and the two fifth reinforcing members. When the fifth reinforcing members and the sixth reinforcing members are folded outward, and the first reinforcing member is folded toward and attached to the second reinforcing member, the cover is rotated to support the back of the receiving portion.

### FIELD

The subject matter herein generally relates to a protection device for an electronic device.

### BACKGROUND

Electronic devices are often used with a protection device to protect the device from damage or shock. The protection device can be a simple case or a complex cover.

### BRIEF DESCRIPTION OF THE DRAWINGS

Implementations of the present technology will now be described, by way of example only, with reference to the figures.

FIG. 1 is an isometric view of an embodiment of a protection device and an electronic device, wherein the protection device includes a receiving portion and a cover portion.

FIG. 2 is an assembled, isometric view of FIG. 1, showing the cover covering the receiving portion.

FIG. 3 is a cross-sectional view along line III-III of FIG. 1.

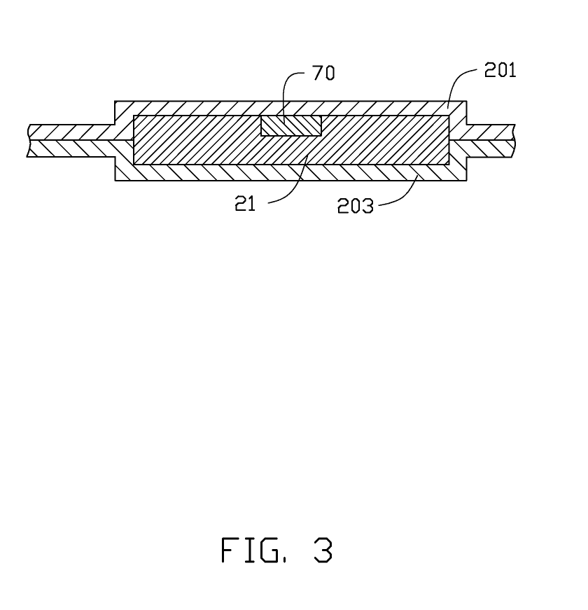

FIG. 4 is an assembled, isometric view of FIG. 1, showing the cover folded to support the receiving portion in a first configuration.

FIG. 5 is similar to FIG. 4, but viewed from another aspect.

FIG. 6 is an assembled, isometric view of FIG. 1, but the cover folded to support the receiving portion in a second configuration.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiment described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure describes a protection device for holding and supporting an electronic device 50.

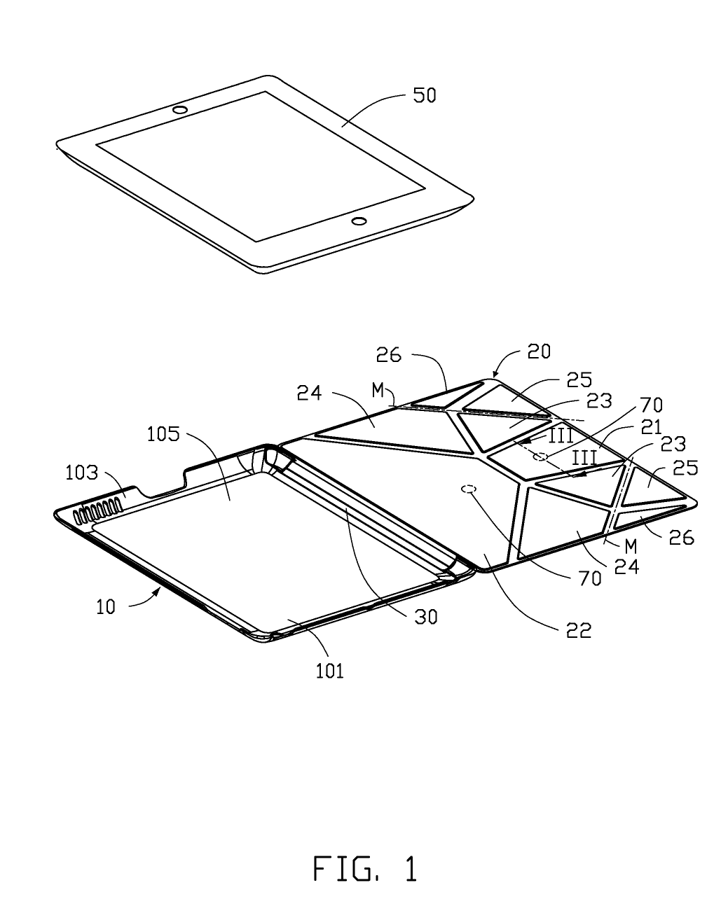

FIG. 1 illustrates an embodiment of a protection device. The protection device includes a receiving portion 10 and a cover portion 20 pivotally connected to the receiving portion 10. In this embodiment, the cover portion 20 is pivotally connected to the receiving portion 10 by a flexible rubber strip 30.

The receiving portion 10 includes a substantially rectangular base board 101 and a peripheral edge 103 extending from edges of the base board 101. The base board 101 and the peripheral edge 103 define a receiving space 105 for holding an electronic device 50. In the embodiment, the electronic device 50 is a handheld device, such as a mobile phone. A first edge of the flexible rubber strip 30 is fixed to the base plate 101. A second edge of the flexible rubber strip 30, opposite and parallel to the first edge is connected to the cover portion 20. In this embodiment, the receiving portion 10 is a hard shell, made of, for example, plastic, carbon fiber or glass fiber.

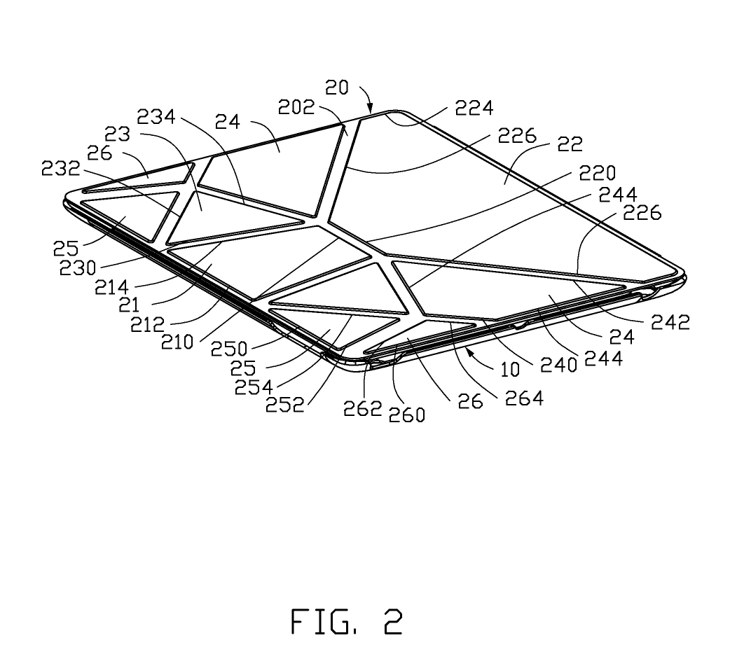

FIGS. 1 and 2 illustrate that the cover portion 20 is substantially rectangular and comprises an isosceles trapezoid-shaped first reinforcing member 21, two hexagon-shaped second reinforcing members 22, two triangle-shaped third reinforcing members 23, two trapezoid-shaped fourth reinforcing members 24, two substantially triangle-shaped fifth reinforcing members 25 and two substantially triangle-shaped sixth reinforcing members 26. Each of the first reinforcing member 21, the second reinforcing members 22, the third reinforcing members 23, the fourth reinforcing member 24, the fifth reinforcing member 25 and the sixth reinforcing members 26 comprise a rigid board encapsulated between a first surface layer 201 and a second surface layer 203 of cover portion 20. The first surface layer 201 is an outer surface of the cover portion 20, formed of, for example, leather, and the second surface layer 203 is an inner surface of the cover portion 20, formed of, for example, superfine fiber layer. In areas positioned between reinforcing members, the first surface layer 201 and the second surface layer 203 are connected together to form fold lines 202 in the areas between the first reinforcing member 21, the second reinforcing member 22, the third reinforcing member 23, the fourth reinforcing member 24, the fifth reinforcing member 25 and the sixth reinforcing members 26. Each of the first reinforcing member 21, the second reinforcing member 22, the third reinforcing member 23, the fourth reinforcing member 24, the fifth reinforcing member 25 and the sixth reinforcing members 26 may comprises rigid board materials, such as fiberglass, carbon fiber board, cardboard or plastic board.

Each of the first reinforcing member 21 and the second reinforcing member 22 comprise a plurality of embedded magnets 70. When first reinforcing member 21 is folded to attach the second reinforcing member 22, the magnet 70 of the first reinforcing member 21 is attracted to the magnet 70 of the second reinforcing member 22.

The first reinforcing member 21 located at a middle of a side of the cover portion 20 away from the flexible rubber strip 30, comprises a first base 210, a second base 212 parallel to the first base 210 and longer than the first base 210, and a pair of sides 214 slantingly connected between the first base 210 and the second base 212. The second reinforcing member 22 located at a side of the cover portion 30 adjacent to the flexible rubber strip 30, comprises a first side 220, a second side 222 parallel to the first side 220 and longer than the first side 220, two third sides 224 perpendicular to the second side 222, and two fourth sides 226 slantingly connected between the first side 220 and two third sides 224. Each second reinforcing member 23 comprises a first side 230, a second side 232 and a third side 234. The fourth reinforcing member 24 comprises a first base 240, a second base 242 parallel to the first base 240 and longer than the first base 240, and a pair of sides 244 slantingly connected between the first base 240 and the second base 242. Each fifth reinforcing member 25 comprises a first side 250, a second side 252 and a third side 254. Each sixth reinforcing member 26 comprises a first side 260, a second side 262 and a third side 264.

The second base 222 of the second reinforcing member 22 is adjacent to the flexible rubber strip 30. The first base 210 of the first reinforcing member 21 is adjacent the first base 220 of the second reinforcing member 22. The second base 212 of the first reinforcing member 21 and the two first sides 250 of the fifth reinforcing members 25 lie along a straight line. Each side 214 of the first reinforcing member 21 is adjacent and parallel to the first side 230 of the third reinforcing member 23. The second side 232 is adjacent and parallel to the third side 254 of the fifth reinforcing member 25. The second side 252 of the fifth reinforcing member 25 is adjacent and parallel to the second side 262 of the sixth reinforcing member 26. The first side 260 of the sixth reinforcing member 26, a side 244 of the fourth reinforcing member 24 and the third side 224 of the second reinforcing member 22 lie along a straight line. The first base 240 of the fourth reinforcing member 24 is adjacent and parallel to the third side 264 of the sixth reinforcing member 26. A side 244 of the fourth reinforcing member 24 is adjacent and parallel to the third side 234 of the second reinforcing member 23. The second base 242 of the fourth reinforcing member 24 is adjacent and parallel to the fourth sides 226 of the second reinforcing member 22.

The electronic device 50 is held in the receiving space 105 of the receiving portion 10, and the cover portion 20 can be rotated to cover the receiving portion 10 to protect the electronic device 50.

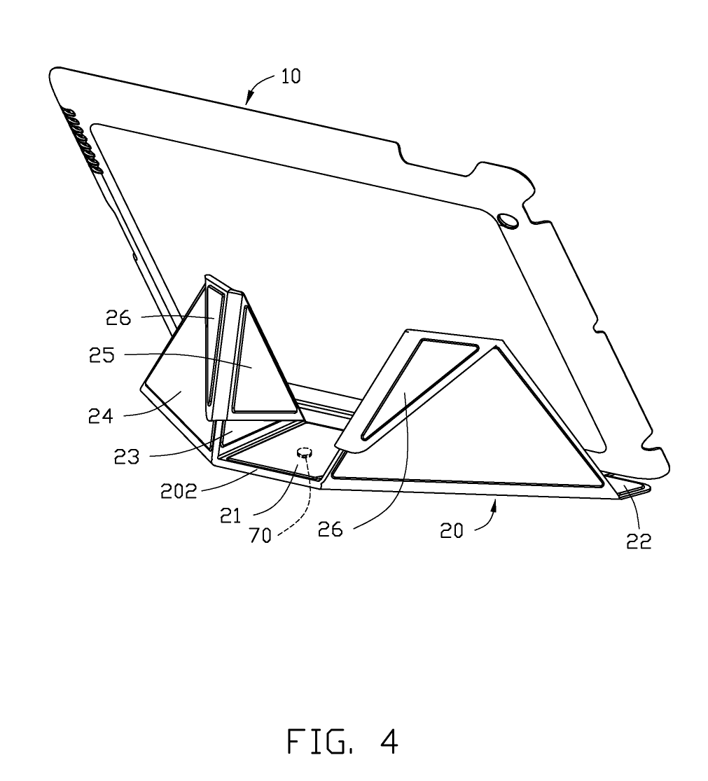

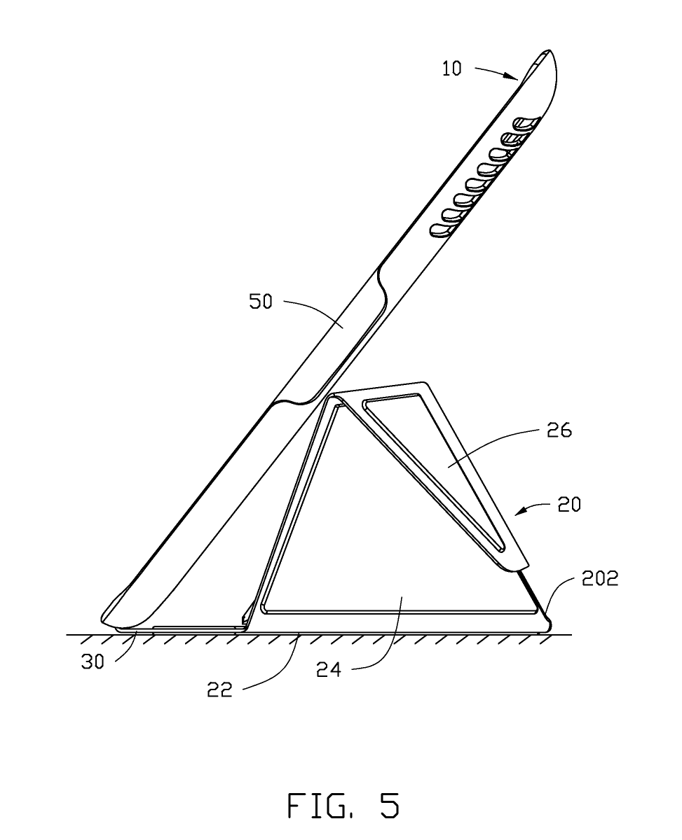

FIGS. 1, 4 and 5 illustrate the electronic device 50 when supported by the cover portion 20 folded in a first configuration. The cover portion 20 is rotated toward an outside of the cover 10. The fifth reinforcing members 25 as well as the sixth reinforcing members 26 are folded along the line M outward respectively. The first reinforcing member 21 is folded along fold lines to attach with and attract the second reinforcing member 22 by the magnets 70 embedded therein. And the two third reinforcing members 23 connect between the first reinforcing members 21 and the fourth reinforcing members 24, the two fourth reinforcing members 24 connect between the second reinforcing members 22 and the third reinforcing members 23, the fifth reinforcing members 25 are located outside of the third reinforcing member 23, and the two sixth reinforcing members 26 are respectively located outside of the two fourth reinforcing members 24.

The folded cover portion 20 is rotated toward the receiving portion 10. The folded cover portion 20 supports a back of the receiving portion 10 with the electronic device 50 received in the receiving portion 10. The fold lines 202 between the first reinforcing member 21 and the second reinforcing member 22, and a bottom of the receiving portion 10 connected to the flexible rubber strip 30 are supported on one plane, such as a desk. In this embodiment, the angle between the receiving portion 10 and the plane is approximately 52 degrees.

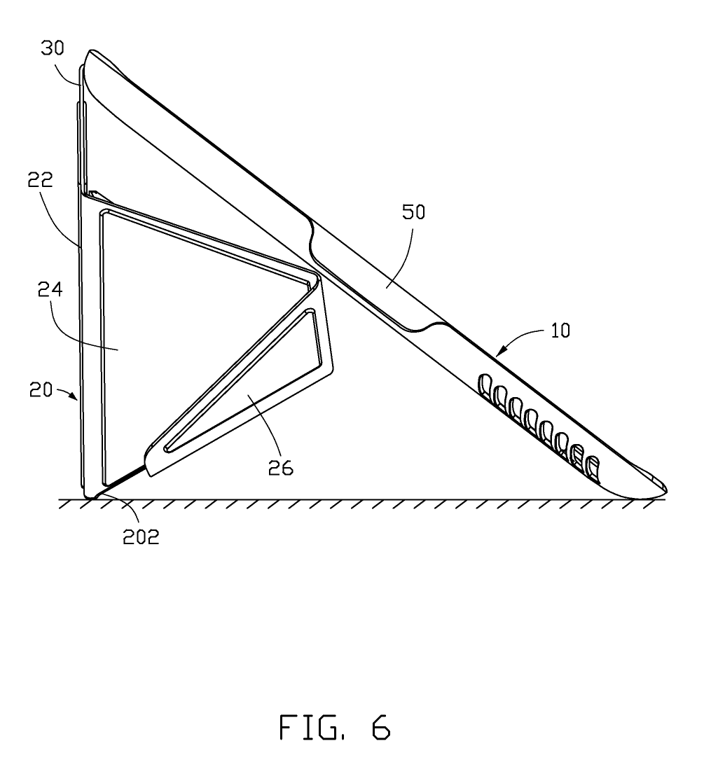

FIG. 6 illustrates that the fold line 202 and a side of the receiving portion 10 away from the flexible rubber strip 30 can be supported on the plane. And the angle between the receiving portion 10 and the plane is approximately 38 degrees.

The receiving portion 10 of the protection device 100 can hold the electronic device 50 and the cover portion 20 can be rotated to cover the receiving portion 10 and protect the electronic device 50. And the folded cover portion 20 can support the electronic device 50 at different angles.

It is to be understood, however, that even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A protection device comprising:
a receiving portion for receiving an electronic device therein; and
a cover portion pivotally connected to the receiving portion to cover the electronic device, the cover portion comprising a first reinforcing member, a second reinforcing member, two third reinforcing members symmetrically positioned on two opposite sides of the first reinforcing member, two fourth reinforcing members located between the two third reinforcing members and the second reinforcing member, two fifth reinforcing member symmetrically positioned on two opposite sides of the third reinforcing member, and two sixth reinforcing members respectively located between the two fourth reinforcing members and the two fifth reinforcing members;
wherein the first, second, third, fourth, fifth and sixth reinforcing members are foldably connected to each other by fold lines between the reinforcing members; and
wherein the fifth reinforcing members and the sixth reinforcing members are folded outward, and the first reinforcing member is folded toward and attached to the second reinforcing member, the cover portion is rotated to support a back of the receiving portion.

2. The protection device of claim 1, wherein the receiving portion comprises a base board and peripheral edges extending from the edge of the base board, the base board and the peripheral edges defining a receiving space for holding the electronic device.

3. The protection device of claim 1, wherein the cover is connected to the receiving portion by a flexible rubber strip.

4. The protection device of claim 3, wherein the first reinforcing member is isosceles trapezoid and located at a middle of a side of the cover portion away from the flexible rubber strip, the second reinforcing member is hexagon and is located at a side of the cover portion adjacent to the flexible rubber strip.

5. The protection device of claim 4, wherein the first reinforcing member comprises a first base, a second base parallel to the first base and longer than the first base, and a pair of sides slantingly connected between the first base and the second base, the second reinforcing member comprises a first side, a second side parallel to the first side and longer than the first side, two third sides perpendicular to the second side, and two fourth sides slantingly connected between the first side and two third sides and the first base of the first reinforcing member is beside the first base of the second reinforcing member.

6. The protection device of claim 4, wherein the two third reinforcing members are triangular and symmetrically located at opposite sides of the first reinforcing member, the two fourth reinforcing members are trapezoidal and symmetrically located between the two second reinforcing members and the two third reinforcing members.

7. The protection device of claim 6, wherein each second reinforcing member comprises a first side, a second side and a third side, the fourth reinforcing member comprises a first base, a second base parallel to the first base and longer than the first base, and a pair of sides slantingly connected between the first base and the second base, each side of the first reinforcing member is adjacent and parallel to the first side of the third reinforcing member, a side of the fourth reinforcing member is adjacent and parallel to the third side of the second reinforcing member, the second base of the fourth reinforcing member is adjacent and parallel to the fourth sides of the second reinforcing member.

8. The protection device of claim 6, wherein the two fifth reinforcing members are triangular and symmetrically positioned on two second sides of the third reinforcing member, the two sixth reinforcing members are triangular and symmetrically located between the two fifth reinforcing members and the two fourth reinforcing members.

9. The protection device of claim 8, wherein each fifth reinforcing member comprises a first side, a second side and a third side, each sixth reinforcing member comprises a first side, a second side and a third side, the second side of the third reinforcing member is adjacent and parallel to the third side of the fifth reinforcing member, the second side of the fifth reinforcing member is adjacent and parallel to the second side of the sixth reinforcing member, the first base of the fourth reinforcing member is adjacent and parallel to the third side of the sixth reinforcing member, the second base of the first reinforcing member and the two first sides of the fifth reinforcing members lie along a straight line, the first side of the sixth reinforcing member, a side of the fourth reinforcing member and the third side of the second reinforcing member lie along a straight line.

10. The protection device of claim 1, wherein the first reinforcing member and the second reinforcing member comprise a plurality of magnets embedded therein for attracting the first reinforcing member and the second reinforcing member.

11. The protection device of claim 1, wherein the first, second, third, fourth and fifth reinforcing members comprise rigid boards.

12. The protection device of claim 11, wherein the rigid boards of the first, second, third, fourth and fifth reinforcing members are encapsulated between a first surface layer and a second surface layer of cover portion, the first surface layer is an outer surface of the cover portion, and the second surface layer is an inner surface of the cover portion, in areas between reinforcing members, the first surface layer and the second surface layer are connected together to form fold lines between the first, second, third, fourth and fifth reinforcing members by the leathern layer and the fiber layer connected together.

13. A cover comprising:
a first reinforcing member, a second reinforcing member, two third reinforcing members symmetrically located at two opposite sides of the first reinforcing member, two fourth reinforcing members located between the two third reinforcing members and the second reinforcing member, two fifth reinforcing member symmetrically positioned on two opposite sides of the third reinforcing member, and two sixth reinforcing members respectively located between the two fourth reinforcing members and the two fifth reinforcing members;
wherein the first, second, third, fourth, fifth and sixth reinforcing members are foldably connected to each other by fold lines between the reinforcing members; and
wherein the fifth reinforcing members and the sixth reinforcing members are folded outward, and the first reinforcing member is folded toward and attached to the second reinforcing member.

14. The cover of claim 13, wherein the first reinforcing member is isosceles trapezoid, the second reinforcing member is hexagon, the first reinforcing member comprises a first base, a second base parallel to the first base and longer than the first base, and a pair of sides slantingly connected between the first base and the second base, the second reinforcing member comprises a first side, a second side parallel to the first side and longer than the first side, two third sides perpendicular to the second side, and two fourth sides slantingly connected between the first side and two third sides and the first base of the first reinforcing member is beside the first base of the second reinforcing member.

15. The cover of claim 14, wherein the two third reinforcing members are triangular and symmetrically positioned on opposite sides of the first reinforcing member, the two fourth reinforcing members are trapezoidal and symmetrically located between the two second reinforcing members and the two third reinforcing members.

16. The cover of claim 15, wherein each second reinforcing member comprises a first side, a second side and a third side, the fourth reinforcing member comprises a first base, a second base parallel to the first base and longer than the first base, and a pair of sides slantingly connected between the first base and the second base, each side of the first reinforcing member is adjacent and parallel to the first side of the third reinforcing member, a side of the fourth reinforcing member is adjacent and parallel to the third side of the second reinforcing member, the second base of the fourth reinforcing member is adjacent and parallel to the fourth sides of the second reinforcing member.

17. The cover of claim 15, wherein the two fifth reinforcing members are triangular and symmetrically located at two second sides of the third reinforcing member, the two sixth reinforcing members are triangular and symmetrically positioned between the two fifth reinforcing members and the two fourth reinforcing members.

18. The cover of claim 17, wherein each fifth reinforcing member comprises a first side, a second side and a third side, each sixth reinforcing member comprises a first side, a second side and a third side, the second side of the third reinforcing member is adjacent and parallel to the third side of the fifth reinforcing member, the second side of the fifth reinforcing member is adjacent and parallel to the second side of the sixth reinforcing member, the first base of the fourth reinforcing member is adjacent and parallel to the third side of the sixth reinforcing member, the second base of the first reinforcing member and the two first sides of the fifth reinforcing members lie along a straight line, the first side of the sixth reinforcing member, a side of the fourth reinforcing member and the third side of the second reinforcing member lie along a straight line.

19. The cover of claim 13, wherein the first reinforcing member and the second reinforcing member comprise a plurality of magnets for attracting the first reinforcing member and the second reinforcing member.
